(19) United States
(12) Patent Application Publication
(10) Pub. No.: US 2011/0301892 A1
(43) Pub. Date: Dec. 8, 2011

(54) System and method for characterizing the electrical properties of a semiconductor sample

(76) Inventor: Emil Kamieniecki, Bedford, MA (US)

(21) Appl. No.: 12/932,174

(22) Filed: Feb. 18, 2011

Related U.S. Application Data
(60) Provisional application No. 61/396,853, filed on Jun. 3, 2010.

(51) Int. Cl. G01R 29/00; G06F 19/00

(52) U.S. Cl. 702/65; 324/97

(57) ABSTRACT

A system for characterizing the electrical properties of semiconductor wafers with high surface state densities, such as GaN wafers, includes a support subsystem for supporting the semiconductor sample, at least one light source for illuminating a spot on the sample, and a detection subsystem for measuring the photovoltage signal produced from illumination of the sample. In use, the system utilizes in-line, non-contact photovoltage techniques that exploits the presence of the high surface state density and the known components of its associated electrostatic barrier as part of its novel characterization process. Specifically, the system illuminates the sample with one or more light beams that vary in photon energy and duration in order to excite charge carriers in specific layers of the sample while either preserving or collapsing the electrostatic barrier. In this manner, the system is able to electrically characterize individual or combined layers of the sample as well as embedded junctions.

### CROSS-REFERENCE TO RELATED APPLICATIONS

The present application claims the benefit under 35 U.S.C. 119(e) of U.S. provisional patent application Ser. No. 61/396,853, filed Jun. 3, 2010, the disclosure of which is incorporated herein by reference.

### TECHNICAL FIELD

The present invention relates generally to semiconductor characterization and more particularly to systems and methods for determining basic electrical parameters of the thin films and layers that form multi-layer semiconductor wafer structures.

### BACKGROUND ART

Semiconductors are well known in the art and are commonly used in the manufacture of a wide variety of electronic devices including light emitting diodes, lasers, photo-detectors, transistors, solar cells, diodes, silicon controlled rectifiers and integrated circuits. Semiconductors are commonly constructed as wafers using one or more types of semiconducting materials, such as silicon, germanium, gallium arsenide and silicon carbide.

Due to its unique properties, Gallium Nitride (GaN) is commonly utilized to construct semiconductor wafer structures that are in turn used to construct High Brightness Light Emitting Diodes (HB-LEDs). Referring now to FIG. 1, there is shown a simplified section view of an example of a semiconductor sample 11 formed using thin layers of Gallium Nitride. As can be seen, semiconductor sample 11 comprises a wafer substrate 13 (most commonly a sapphire substrate) on which is disposed a multi-layer stack 15 of thin films. As can be seen, stack 15 includes an active junction region 17 formed from multiple quantum wells (MQW) of InₓGa₁₋ₓN/GaN that is in turn sandwiched between a top cladding layer 19 formed from Magnesium (Mg) doped p-type GaN and a bottom cladding layer 21 formed from n-type GaN.

A number of methods for growing the multilayer structure of semiconductor samples of the type described above are known in the art, including metalorganic chemical vapor deposition (MOCVD) and molecular beam epitaxy (MBE). However, it has been found that, in general, GaN layers formed by growth methods, such as MOCVD, which is the predominant growth process in the HB-LED industry, and doped with p-type material such as magnesium, typically suffer from a notable drawback. Specifically, GaN layers formed by growth methods commonly behave like a semi-insulating or high-resistive material as a result of hydrogen passivation (i.e., hydrogen that is bonding with the p-type dopant in the reaction chamber and thus preventing the large percentage of Mg in the GaN from behaving as an active acceptor state).

In response to the hydrogen passivation phenomena and high Mg ionization energy, a high initial “chemical” concentration of the p-type dopant (e.g., Mg) is typically required in order to achieve the electrically active doping concentration in p-type GaN that is required to form the p-n junction of an LED. However, it has been found this relatively high level of “chemical” doping in turn degrades the electronic properties of the p-type GaN, which is highly undesirable.

Accordingly, it has been found that there is a distinct need in the HB-LED manufacturing industry for in-line process control and monitoring of the electrical characteristics of GaN. Presently, there are two primary techniques that are used in the HB-LED industry to monitor the electronic properties of Gallium Nitride: (i) Hall measurements of carrier concentration and (ii) room temperature photoluminescence (PL).

Hall measurements are used to determine carrier density of a semiconductor layer through current and voltage measurements and, as such, require cutting the semiconductor wafer sample into smaller pieces (typically 10 mm×10 mm) and making ohmic contacts. Although well known and widely used to make electrical measurements of GaN layers in the HB-LED industry, the use Hall measurements has been found to suffer from a number of notable shortcomings.

As a first shortcoming, the requirement precludes Hall measurements from being performed on the actual product wafers but rather requires the preparation of special measurement wafers that include a single active layer.

As a second shortcoming, the requirement that the semiconductor wafer sample be cut into a number of smaller pieces in order to make a Hall measurement renders the overall process rather cumbersome and time-consuming to complete.

As a third shortcoming, Hall measurements can be used to determine the carrier concentration of Mg doped GaN but cannot be similarly used to determine the doping concentration. Since wide band gap semiconductors, such as GaN, have a doping, or acceptor, concentration that is often substantially higher (10 to 100 times higher) than its corresponding carrier concentration, the use of Hall measurements to characterize the critical electrical characteristics of GaN has been found to be largely ineffective.

Room temperature photoluminescence is used to determine the electronic structure of GaN by illuminating the surface of the semiconductor material with a light signal. The light signal is absorbed into the material and excites electrons present therein. This excitation creates excess energy in the material that is released as photon energy that can be measured using non-contact means, thereby rendering photoluminescence desirable as an in-line characterization technique that can be performed directly on the product wafers.

However, while spectral measurements made using room temperature photoluminescence have been found to be useful in determining the quality of semiconductor wafers and overall process reproducibility, the spectral measurements are not sufficient, in most of the cases, to determine the cause of process malfunction or non-uniformity. Accomplishing this task requires additional electrical property measurements that are typically performed using routine, off-line Hall measurements.

As a result of the aforementioned drawbacks commonly associated with the electrical characterization techniques noted above, it has been found that there is a distinct need for an alternative approach for non-contact, in-line determination of the doping concentration of GaN.

Well known non-contact, in-line electrical characterization techniques that are commonly used in connection with silicon wafer structures are based on capacitance versus voltage measurements (or its equivalents) using Surface Photovoltage (SPV) effect. These methods are based on the measurement of an incremental change of the space-charge capacitance for the material in response to an incremental change in its surface potential (e.g., using either externally applied voltage or corona charging).

Although well known and widely used in the characterization of samples with a relatively high quality surface (i.e., a surface with a low density of surface states), such as silicon, traditional SPV-based techniques are not similarly utilized in the art in connection with semiconductor samples with extremely high surface state density, such as GaN. Specifically, SPV-based techniques are not used with GaN-type materials due to the presence of a high density of surface state charge. This charge electrically shields the interior of the top layer (e.g., the subsurface region 25 of top cladding layer 19) from the externally applied voltage or charge. As a result, subsurface charge carriers excited beneath an electrostatic barrier formed at the outer surface of a semiconductor sample cease to modulate the electrostatic barrier to the extent necessary to electrically characterize the top layer.

As noted above, a high density of surface state charge serves to create an electrostatic barrier at its surface (i.e., exposed outer surface 23). This electrostatic barrier is created due to a pinning of the Fermi level at the surface that is constant and independent of the doping concentration of the top layer, this condition commonly being referred to as “Fermi Level Pinning (FLP)” in the art.

### SUMMARY OF THE INVENTION

It is an object of the present invention to provide a novel system and method for characterizing the electrical properties of a semiconductor sample.

It is another object of the present invention to provide a system and method as described above which is effective in characterizing the electrical properties of a semiconductor sample with a high density of surface state charge, such as a Gallium Nitride (GaN)-based semiconductor sample.

It is yet another object of the present invention to provide a system and method as described above which allows for in-line process control and monitoring of the electrical characteristics of the semiconductor sample during its manufacture.

It is yet still another object of the present invention to provide a system and method as described above which allows for electrical characterization of the semiconductor sample using non-contact means.

Accordingly, as one feature of the present invention, there is provided a method for characterizing electrical properties of a semiconductor sample, the semiconductor sample comprising an active junction region disposed between at least one top cladding layer and at least one bottom cladding layer, the at least one top cladding layer having an exposed outer surface and a subsurface region beneath the exposed outer surface, the exposed outer surface having a surface-state charge that forms an electrostatic barrier, the method comprising the steps of (a) illuminating the outer surface of the at least one top cladding layer with a first intensity modulated light beam that penetrates through the at least one top cladding layer and into the active junction region so as to produce charge carriers in both the subsurface region of the at least one top cladding layer and the active junction region, the first intensity modulated light beam being adapted to preserve the electrostatic barrier and thereby yield a first photovoltage signal on the exposed outer surface that represents electrical properties associated with both the subsurface region of the at least one top cladding layer and the active junction region; (b) measuring the first photovoltage signal on the exposed outer surface of the semiconductor sample; (c) illuminating the exposed outer surface of the at least one top cladding layer with a second intensity modulated light beam that penetrates through the at least one top cladding layer and into the active junction region, the second intensity modulated light beam being adapted to produce a second photovoltage signal on the exposed outer surface that represents electrical properties associated only with the active junction region; (d) measuring the second photovoltage signal on the exposed outer surface of the semiconductor sample; and (e) subtracting the second photovoltage signal from the first photovoltage signal to yield a sample characterization signal, the sample characterization signal representing electrical properties associated with the subsurface region of the at least one top cladding layer.

Accordingly, as another feature of the present invention, there is provided a system for characterizing electrical properties of a semiconductor sample, the semiconductor sample comprising an active junction region disposed between at least one top cladding layer and at least one bottom cladding layer, the at least one top cladding layer having an exposed outer surface and a subsurface region beneath the exposed outer surface, the exposed outer surface having a surface-state charge that forms an electrostatic barrier, the system comprising (a) a support subsystem for supporting the semiconductor sample; (b) at least one light source for illuminating at least a region of the outer surface of the at least one top cladding layer to excite charge carriers with the semiconductor sample so as to create a surface photovoltage signal; (c) a detection subsystem for measuring the surface photovoltage signal; and (d) a controller in electrical communication with the detection subsystem for analyzing the surface photovoltage signal to characterize electrical properties of the semiconductor sample; (e) wherein the at least one light source illuminates the semiconductor sample with at least one intensity modulated light beam that penetrates through the at least one top cladding layer and into the active junction region so as to produce charge carriers in both the subsurface region of the at least one top cladding layer and the active junction region, the first intensity modulated light beam being adapted to preserve the electrostatic barrier and thereby yield a first photovoltage signal on the exposed outer surface that represents electrical properties associated with both the subsurface region of the at least one top cladding layer and the active junction region, the at least one light source additionally illuminating the semiconductor sample with a second intensity modulated light beam that penetrates through the at least one top cladding layer and into the active junction region, the second intensity modulated light beam being adapted to produce a second photovoltage signal on the exposed outer surface that represents electrical properties associated only with the active junction region.

Additional objects, as well as features and advantages, of the present invention will be set forth in part in the description which follows, and in part will be obvious from the description or may be learned by practice of the invention. In the description, reference is made to the accompanying drawings which form a part thereof and in which is shown by way of illustration various embodiments for practicing the invention. The embodiments will be described in sufficient detail to enable those skilled in the art to practice the invention, and it is to be understood that other embodiments may be utilized and that structural changes may be made without departing from the scope of the invention. The following detailed description is, therefore, not to be taken in a limiting sense, and the scope of the present invention is best defined by the appended claims.

### BRIEF DESCRIPTION OF THE DRAWINGS

The accompanying drawings, which are hereby incorporated into and constitute a part of this specification, illustrate an embodiment of the invention and, together with the description, serve to explain the principles of the invention. In the drawings, wherein like reference numerals represent like parts:

FIG. 1 is a cross-section view of a simplified semiconductor wafer structure that is well known in the art;

FIG. 2 is a simplified schematic representation of a semiconductor characterization system constructed according to the teachings of the present invention;

FIG. 3 is a band diagram for a p-type semiconductor under depletion conditions;

FIG. 4 is a simplified schematic representation of the semiconductor characterization system of FIG. 2, the system being shown characterizing a semiconductor sample.

FIG. 5 is a chart listing actual measurements of the doping concentration and conductivity type for three different GaN-based semiconductor samples using the system of FIG. 2; and

FIG. 6 is a chart listing actual measurements of the junction width and shunt resistance for four different semiconductor wafer samples using the system of FIG. 2.

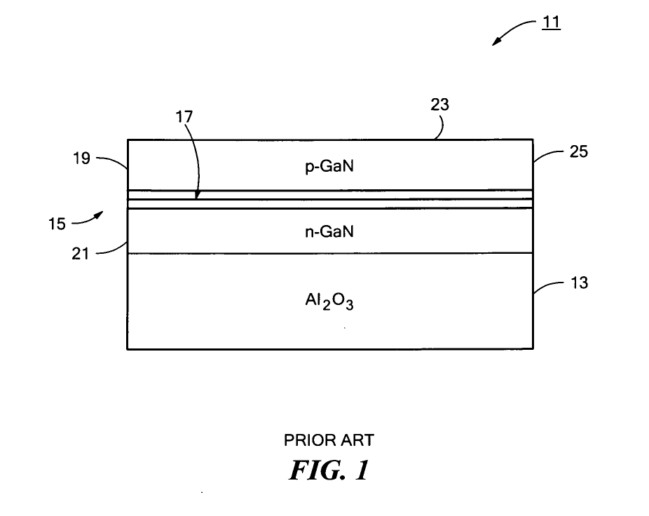

### DETAILED DESCRIPTION OF PREFERRED EMBODIMENTS

### Semiconductor Characterization System 111

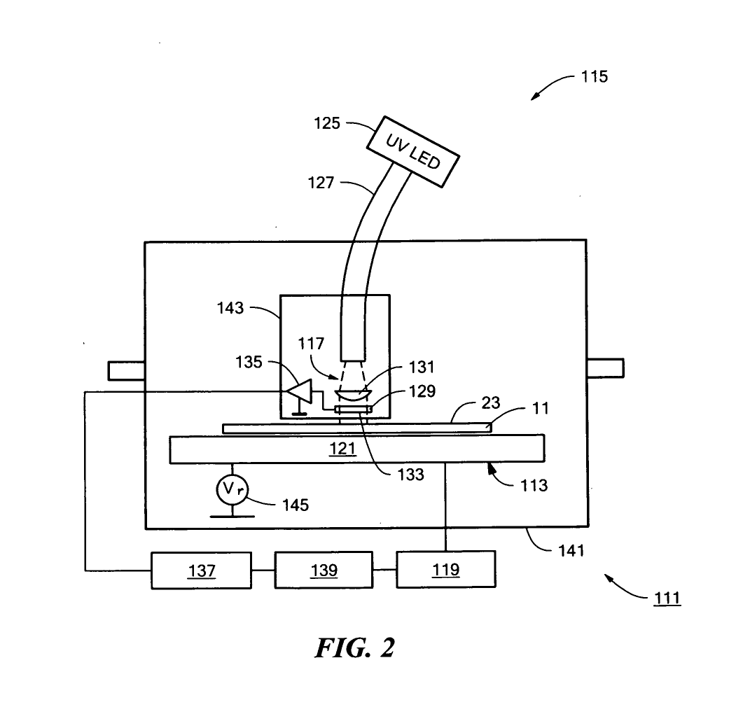

Referring now to FIG. 2, there is shown a system for characterizing the electrical properties of a semiconductor wafer structure, the system being constructed according to the teachings of the present invention and identified generally by reference numeral 111. As will be described in detail below, system 111 is principally designed to apply novel in-line, non-contact surface photovoltage (SPV) techniques to semiconductor wafer structures with high surface state densities, which is a principal object of the present invention. Although conventional surface photovoltage techniques are not typically applied to semiconductor wafer structures with high surface state densities, such as GaN, due to the inherent electrostatic shielding of the interior of the top layer (e.g., the subsurface region 25 of top cladding layer 19) from the externally applied voltage or charge, it is to be understood that the system and method of the present invention is not only capable of electrically characterizing individual layers in semiconductor materials with high surface state densities but actually exploits the presence of the high surface state density and the known components of its associated electrostatic barrier (namely, the height and associated space-charge capacitance of the barrier) as part of the novel characterization process.

For purposes of simplicity only, system 111 is described herein in connection with the electrical characterization of top cladding layer 19 and/or active junction region 17 of GaN-based semiconductor wafer sample 11. However, it is to be understood that system 111 is not limited to the electrical characterization of GaN-based wafer structures. Rather, it should be noted that system 111 could be similarly utilized to electrically characterize the thin films and layers of alternative types of semiconductor materials without departing from the spirit of the present invention.

As defined herein, use of the term “semiconductor wafer structure” denotes any article having one or more semiconductor layers that may be used in or comprise all or part of at least one electronic or opto-electronic component. In particular “LED wafer structure” or “LED structure” means an article having one or more semiconductors layers that may be used in or comprise all or part of LED component. In the formulas and in the figures the subscripts “o” refer to the thermal equilibrium conditions, the subscripts “s” refer to the surface and subsurface region of the top cladding layer, and the subscripts “j” refer to the junction.

As seen most clearly in FIG. 2, system 111 comprises a support subsystem 113 on which sample 11 is mounted, a light source 115 for illuminating a region, or spot, on exposed outer surface 23 to excite charge carriers within semiconductor sample 11 so as to create a photovoltage signal, a detection subsystem 117 for measuring the photovoltage signal on outer surface 23, and a controller 119 for regulating the principal operations for system 111, as will be described further in detail below.

Support subsystem 113 is represented herein as comprising a wafer support, or chuck, 121 on which semiconductor sample 11 is mounted, wafer support 121 preferably being coated with a thin insulating layer for protection.

It should be noted that wafer support 121 is preferably connected to controller 119 and adapted for incremental displacement so that each sub-region of semiconductor wafer sample 11 can be individually illuminated for electrical characterization (i.e., in a spot-by-spot manner or through continuous movement). In this capacity, controller 119 can regulate the position of wafer support 121 so that the entire outer surface 23 of wafer sample 11 can be electrically characterized and mapped to facilitate wafer analysis, which is highly desirable.

Light source 115 is represented herein as comprising at least one light emitter 125 that is adapted to generate a light beam of a specified wavelength and intensity, such as an ultraviolet light emitting diode (UV LED). It should be noted that each light emitter 125 could be periodically intensity modulated using an electronic driver, opto-electronic modulator or mechanical chopper.

As will be described further in detail below, light source 115 is preferably designed to generate multiple light beams of varying wavelength, intensity and duration. Accordingly, although light source 115 is represented herein as comprising a single light emitter 125 for generating each of the plurality of light beams, it is to be understood that multiple light emitters could be implemented into system 111 without departing from the spirit of the present invention, each light emitter being designated to generate a light beam of a specified wavelength and intensity.

For example, light source 115 may include (i) a first light emitter that generates light with a photon energy that is greater than the band gap of cladding layer 19 (i.e., light with a wavelength shorter than 350 nm, such as light with a typical peak wavelength of 285 nm), such as UV LED model number UVTOP280 that is currently manufactured and rendered commercially available by Sensor Electronic Technology (SET), Inc., and (ii) a second light emitter that generates light (essentially monochromatic light) with a photon energy that is less than the band gap of cladding layer 19 (i.e., light with a wavelength longer than 350 nm), such as LED model number UVTOP355 that is currently manufactured and rendered commercially available by SET, Inc. It should be noted that the light emitted from the second light emitter is preferably filtered using filtering device made of the cladding layer material (e.g., a GaN mono-crystalline filter having a thickness of about 0.5 mm) in order to minimize the effect of any illumination of photon energy that exceeds the band gap of top cladding layer 19 that, in turn, could produce a photovoltage signal associated with top cladding layer 19.

Light generated from light emitter 125 is directed toward exposed outer surface 23 of wafer 11 via a light guide 127, such as a fiber optic cable, with one end of light guide 127 being coupled to light emitter 125 and the opposite end of light guide 127 being coupled to a homogenizer 129. As can be appreciated, homogenizer 129, which may be in the form of a 2 mm diameter fused silica rod, assures uniform illumination of the light beam on the intended region, or spot, of wafer 11.

It should be noted that if multiple light emitters 125 are utilized, light guide 127 preferably has a bifurcated construction at one end, with each branch of the bifurcated end being coupled to a corresponding light emitter.

Light source 115 may additionally include collimating optics 131, such as one or more fused silica lenses or gradient index lens. In use, collimating optics 131 serve to collimate the light beam so that dimension of the target area on wafer sample 11 that is illuminated by the light beam will not vary in response to changes in the distance between light source 115 and wafer sample 11.

Detection subsystem 117 comprises, inter alia, a conductive pick-up electrode 133 spaced a near constant distance away from outer surface 25 of sample 11, a preamplifier 135 electrically connected to electrode 133, a lock-in amplifier 137 electrically connected to preamplifier 135 and an analog-to-digital (A/D) converter 139 electrically connected to amplifier 137. Controller 119 is electrically connected to A/D converter 139 and is designed to store and analyze the digital signal generated therefrom.

Electrode 133 is preferably in the form of a partially transparent thin film of indium-tin-oxide (ITO) that is directly disposed onto (or, in the alternative, spaced slightly apart from) the underside surface of homogenizer 129 (i.e., the surface of homogenizer 129 that faces wafer sample 11). As noted briefly above, transparent conductive electrode 133 is preferably maintained at a near constant distance away from wafer sample 11 and serves to detect the presence of photovoltage signals on wafer sample 11 (i.e., using non-contact means).

Preamplifier 135 is preferably in the form of a unity gain amplifier with high input resistance and low input capacitance (i.e., high input load impedance) that is electrically connected to electrode 133 by a lead line, or wire. Preferably, preamplifier 135 is located in close proximity to pickup electrode 133 to reduce input capacitance.

Lock-in amplifier 137 represents one or more parallel lock-in amplifiers that are electrically connected to preamplifier and serve to convert the electrical signal amplified by preamplifier 135 into a direct current voltage signal. The analog DC voltage signal is then converted by A/D converter 139 into a corresponding digital DC voltage signal which is, in turn, stored and analyzed by controller 119 for, among other things, layer-specific wafer mapping, which is highly desirable.

One or more selected components of system 11 (e.g., pick-up electrode 133, preamplifier 135 and wafer chuck 113) are preferably housed within an outer protective enclosure 141 that is filled with a hydrogen-based gas (e.g., a mixture of 10% hydrogen in nitrogen). As can be appreciated, the presence of the hydrogen gas mixture reduces chemisorptions of oxygen on outer surface 23 and, in fact, even reduces already chemisorbed oxygen, thereby preventing changes of the surface potential for sample 11 due oxygen chemisorptions.

In addition, one or more selected components of system 11 (e.g., homogenizer 129, pick-up electrode 133 and preamplifier 135) are preferably housed within an interior enclosure 143 to form a unitary sensing probe. As can be appreciated, the sensing probe is preferably regulated by controller 119 and is capable of incremental vertical displacement relative to wafer sample 11 by means of a Z-axis motorized stage. Specifically, after wafer sample 11 is placed on support 113, controller 119 activates the stage motor for the probe so that pick-up electrode 133 is spaced a desired distance away from top surface 23 of wafer sample 11 (e.g., a distance in the range of approximately 25-250 μm). It should be noted that the spacing distance utilized by controller 119 is determined either by using the known thickness of substrate 13 for sample 11 (e.g., the thickness of the sapphire substrate for HB-LED wafer structures) or by measuring a distance probing output signal, Vᵣₘ, generated from an alternating current AC voltage source (Vᵣ) 145 that is coupled to wafer support 121.

It should be noted that the distance probing output signal, Vᵣₘ, signal is a measure of a coupling capacitance formed by serially connected capacitances (e.g., between a wafer support, semiconducting layer in sample 11 and pick-up electrode 133). Because preamplifier 135 is preferably in the form of a high input impedance unity gain amplifier, the distance related signal may be weakly dependent on the distance and, as a result, the distance may not require correction during measurement. However, if it is required to maintain this coupling more accurate, the probe stage could be moved during wafer mapping in feedback loop with the signal generated by an ac voltage source (Vᵣ) via the wafer support. The procedure for correcting inaccuracies in the output signal due to low coupling capacitance (Cₚ) in association with sapphire substrate 13 is described further below.

As noted briefly above, controller 119 is responsible for the principal operations of wafer characterization system 11 including, but not limiting to, chuck 113 displacement during the wafer mapping process, vertical positioning of the probe and the intensity of light source 115. Controller 119 is preferably in the form of one or more compute devices, each of which includes one or more programmable processors that are adapted to carry out the novel wafer characterization methods of the present invention.

In particular, controller 119 is preferably designed to process digital signals from A/D converter 139 to determine layer-specific characteristics of wafer sample 11. Although not shown herein, controller 119 preferably includes a filter (not shown) to filter out noise present in the signal that is input into to the analog-to-digital converter. All these functions could be integrated in a digital signal processor (DSP), such as lock-in amplifier model number 7270 manufactured by Signal Recovery, a division of AMETEK, Inc. The digital signal processor may be configured to extract the first harmonic of the signal and separate the first harmonic into two orthogonal components in a function analogous to that performed by an analog lock-in amplifier. The signal from the digital signal processor is then processed by controller 119 for analysis.

### Overview of Electrical Characterization Method

As noted briefly above, system 111 utilizes novel methods for characterizing the electrical properties of semiconductor wafer samples with high surface state densities, such as GaN wafer structures, using in-line, non-contact surface photovoltage (SPV) techniques, which is a principal object of the present invention. Even though SPV techniques are not traditionally applied to semiconductor wafer samples with high surface state densities, the system and methods of the present invention are not only capable of electrically characterizing individual layers in semiconductor materials with high surface state densities but actually exploits the presence of the high surface state density and the known components of its associated electrostatic barrier (namely, the height and associated space-charge capacitance of the barrier) as part of the novel characterization process.

In particular, system 111 is designed to electrically characterize one or more individual layers in semiconductor wafer sample 11 using photovoltage techniques by illuminating outer surface 23 with at least one of the two following light beams: (i) a first intensity modulated light beam that is designed to penetrate through top cladding layer 19 and into active junction region 17, the first intensity modulated light beam being adapted to produce a first photovoltage signal on exposed outer surface 23 that represents electrical properties associated with both subsurface region 25 of top cladding layer 19 and active junction region 17 and (ii) a second intensity modulated light beam that is designed to penetrate through top cladding layer 19 and into active junction region 17, the second intensity modulated light beam being adapted to produce a second photovoltage signal on exposed outer surface 23 that represents electrical properties associated with only active junction region 17.

The first intensity modulated light beam achieves its desired effect by exciting charge carriers in both subsurface region 25 of top cladding layer 19 and active junction region 17 while, at the same time, preserving the presence of the electrostatic barrier at outer surface 23.

Preferably, the first intensity modulated light beam includes the following properties to promote subsurface charge carrier excitation without collapsing the electrostatic barrier: (i) a relatively short wavelength (preferably, less than 355 nm) that is equivalent to a relatively high photon energy (preferably, greater than the band gap of top cladding layer 19) and (ii) a relatively short duration of illumination, or dwell time (preferably, 10-100 msec).

By comparison, the second intensity modulated light beam achieves its desired effect using at least one of the following techniques: (i) by exciting charge carriers in both subsurface region 25 of top cladding layer 19 and active junction region 17 while, at the same time, collapsing the electrostatic barrier at outer surface 23, or (ii) by exciting charge carriers only in active junction region 17 while, at the same time, preserving the presence of the electrostatic barrier at outer surface 23.

Preferably, the first technique (namely, promoting subsurface charge carrier excitation while collapsing the electrostatic barrier) is achieved by utilizing a second intensity modulated light beam with the following properties: (i) a relatively short wavelength (preferably, less than 355 nm) that is equivalent to a relatively high photon energy (preferably, greater than the band gap of top cladding layer 19) and (ii) a relatively long duration of illumination, or dwell time (preferably longer than 1 sec).

Preferably, the second technique (namely, promoting active junction charge carrier excitation while preserving the electrostatic barrier) is achieved by utilizing a second intensity modulated light beam with the following properties: (i) a relatively long wavelength (preferably, greater than 355 nm) that is equivalent to a relatively low photon energy (preferably, less than the band gap of top cladding layer 19) and (ii) a relatively short duration of illumination, or dwell time (preferably, 10-100 msec).

It should be noted that a combination of the two aforementioned techniques for generating the second photovoltage signal could be used to electrically characterize active junction region 17. Specifically, the first technique can be used to initially determine the contribution of active junction 17 to the measured photovoltage signal. Once determined, the second technique (which is considerably faster and substantially higher in sensitivity than the first technique) is preferably implemented to perform rapid electrical characterization of the entire wafer sample 11.

As noted above, the application of the first intensity modulated light beam onto sample 11 produces a first measurable photovoltage signal on outer surface 23 that represents electrical properties associated with both subsurface region 25 and active junction region 17. In addition, the application of the second intensity modulated light beam onto sample 11 produces a second measurable photovoltage signal on outer surface 23 that represents electrical properties associated only with active junction region 17. Accordingly, as a feature of the present invention, it is to be understood that by subtracting the second measurable photovoltage signal from the first measurable photovoltage signal, a resultant sample characterization signal can be calculated that represents electrical properties associated with only subsurface region 25. In this capacity, in-line, non-contact electrical characterization of top cladding layer 25 and active junction region 17 can be determined on either a combined or layer-specific level, which is highly desirable.

As noted above, the system and method of the present invention is not limited to the electrical characterization of a particular type, or structure, of semiconductor sample 11. Rather, it is to be understood that the principals of the present invention could be similarly applied to semiconductor samples of varying construction to electrically characterize one or more of its layers. For example, the system and method of the present invention could be similarly applied to a semiconductor sample that does not necessarily include an active junction region. In this situation, the system and method of the present invention could be used to electrically characterize the subsurface region of the top layer of a semiconductor sample with considerable surface state charge by illuminating its outer surface with a light beam that has the same characteristics as the first intensity modulated light beam described above (i.e., a light beam with a photon energy greater than the band gap of the top layer).

In addition, it should be noted that the characterization techniques set forth in detail above could be similarly applied to a semiconductor sample to characterize a region within its buffer layer (i.e., the region between the substrate and the active junction region). Specifically, a region within the buffer layer can be characterized by inverting the sample (i.e. disposing the sample with its substrate layer facing up), illuminating the exposed bottom surface of the sapphire substrate and then measuring the photovoltage using the techniques of the present invention.

Additional technical details relating to the aforementioned methods for characterizing one or more specific layers of semiconductor sample 11 are described further in detail below.

### Further Technical Details Relating to Electrical Characterization Method

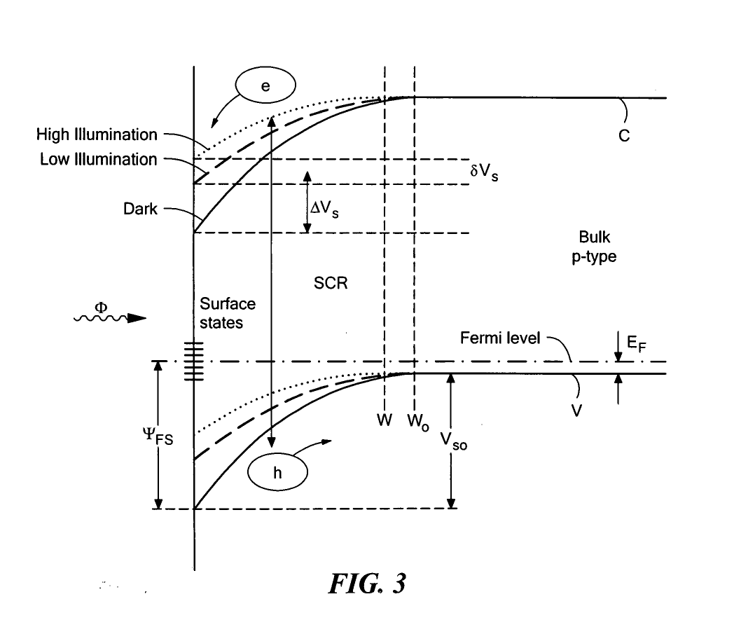

As noted above, to characterize an external cladding layer (e.g., top layer 19) for a semiconductor sample with a high density of surface states (e.g., a GaN-based semiconductor wafer), the method of the present invention exploits the presence of the surface potential barrier formed due to pinning of the Fermi level at the surface at fixed energy relative to conduction and valence band edges. Referring now to FIG. 3, there is shown a band diagram for a p-type semiconductor under depletion conditions. As can be seen, Fermi level pinning, which is independent of the doping level and exists both in p- and n-type GaN, creates a surface space-charge region SCR that is depleted of majority carriers (i.e., the region corresponding to the curved portions of conduction band C and valence band V). This allows for characterization of electrical properties of GaN layers using a method that requires knowledge of (i) the height of the surface potential barrier and (ii) the measurement of the space-charge capacitance (and hence width W of the space-charge region) at surface potential or the surface potential barrier associated with the aforementioned pinning.

The measurement of the space-charge capacitance is accomplished using a surface photovoltage measured capacitance (SPMC) technique that relies upon the illumination of the wafer structure (e.g., sample 11) with periodically intensity modulated (preferably sinusoidally modulated) electromagnetic radiation having a photon energy greater than a band gap of an external cladding layer (e.g., top layer 19) in the wafer structure, the electromagnetic radiation serving to irradiate the surface (e.g., outer surface 23) of the wafer structure. Preferably, the electromagnetic radiation is of sufficiently low intensity to minimize steady-state change of the surface potential barrier, ΔVₛ, and thereby maintain the width of the space-charge region, W, close to its dark value, Wₒ.

Under such low intensity illumination conditions, when the surface potential barrier ΔVₛ is small and the difference between the width of the space-charge region in the dark and under illumination can be neglected, the imaginary component of the ac-SPV signal (quadrature component relative to the incident illumination), Im(δVₛ), is proportional to the reciprocal of the space-charge capacitance, 1/C_{sc}:

$$\vert Im ( δ {V}_{s} ) \vert = q {C}_{sc}^{- 1} δ G \frac{ω {τ}^{2}}{1 + {ω}^{2} {τ}^{2}} \qquad ( A )$$

where q is the elementary charge and δG is the ac component of the minority carrier generation rate in the depletion region:

δG=(1−R)δΦ[1−exp(−αW)] (B)

where δΦ is the ac component of the incident photon flux modulated at the angular frequency ω, R is the reflection coefficient, α is an absorption coefficient, and

$$τ = - \frac{1}{ω} \frac{Im ( δ {V}_{s} )}{Re ( δ {V}_{s} )} \qquad ( C )$$

represents carrier recombination lifetime in the surface region and relates to the density of the carrier recombination centers in this region, Re(δVₛ) is a real (in-phase) component of the ac-SPV signal.

The polarity of the imaginary and real components of δVₛ as measured vs. the phase of the incident illumination, δΦ, depends on the conductivity type of the material and could be used to determine conductivity type of the layer.

For high enough frequencies, such that ω²τ² is much larger than 1, the imaginary component of the ac-SPV signal under low intensity conditions is proportional to the light intensity and is reciprocally proportional to the frequency of light modulation.

The surface space-charge capacitance per unit surface area equals to C_{sc}=∈ₛ/W, where ∈ₛ is the permittivity of the semiconductor. The width of the space-charge (depletion) region in thermal equilibrium and under low illumination conditions is given by:

$${W}_{o} = \sqrt{\frac{2 {ɛ}_{s} \vert {V}_{so} \vert}{q \vert {N}_{sc} \vert}} and hence \vert {N}_{sc} \vert = \frac{2 {ɛ}_{s} \vert {V}_{so} \vert}{{qW}_{o}^{2}} \qquad ( D )$$

where Vₛ is the height of the surface potential barrier and the net doping concentration in the space charge region N_{sc}=N_{D}−N_{A}, N_{D} and N_{A} are the donor and acceptor concentrations in the space-charge region, respectively.

The pinning energy of the Fermi level at the surface measured relative to the Fermi level in the bulk, E_{FS}=qΨ_{FS}, is the sum of the height of the surface potential barrier and Fermi level in the bulk, E_{F} (where E_{F} is measured relative to the corresponding valence or conduction band edge), hence qVₛₒ=E_{FS}−E_{F}. Vₛₒ only weakly depends on the bulk carrier concentration (through E_{F}), thus Wₒ is mainly dependent on the doping concentration (not carrier concentration).

The above equations allow determination of the doping concentration in the space-charge region in top cladding layer 19 of wafer structure 11 when active junction region 17 is located in substantially far from outer surface 23 (i.e., substantially farther than the light penetration depth).

The height of the surface potential barrier associated with surface Fermi level pinning could be also determined by measuring the surface photovoltage caused by a high intensity illumination, which is known in the art.

However, measurement of the surface potential barrier under DC conditions or at low light modulation frequency may be subject to an experimental error due to re-population of the surface states. Optimally, the height of the surface potential barrier associated with surface Fermi level pinning could be determined by measuring surface photovoltage caused by a high intensity illumination pulse, in particular a pulse substantially shorter than the recombination lifetime of minority carriers.

Alternatively, the coefficient that includes the surface potential corresponding to the Fermi level pinning could be determined by calibration, using a wafer with a known electrically active doping concentration. In the case of GaN based LED structures, the calibration wafer is preferably is an n-type GaN wafer that is doped with silicon (however other dopants could be used as well). The calibration coefficient includes both doping concentration and the incident photon flux, thereby eliminating the need for an independent calibration of the incident photon flux. The doping concentration of the n-GaN could be determined using conventional techniques, such as by taking standard Hall effect measurements.

Since the initial known value is E_{FS} and W is dependent on Vₛₒ, determination of the doping concentration (doping density) using ac-SPV requires using an iterative method. This well-known method determines doping concentration by successive approximation of E_{F} using doping concentration from the previous approximation.

In a related embodiment, there is provided a method wherein wafer structure 11 is illuminated with periodically intensity modulated electromagnetic radiation having photon energy greater than a band gap of a relevant layer in the wafer structure, the radiation irradiating the surface of the wafer structure. The electromagnetic radiation is set at a higher intensity such that steady-state surface potential differs substantially from its dark value. The determination of the doping concentration in this case is based on the fact that the ac component of the surface photovoltage signal under higher illumination and high enough light modulation frequencies, such that ω²τ² is much larger than 1, is a function of the light intensity (carrier generation rate, G) and doping concentration only:

δVₛ=f(G,N_{sc}).

Therefore, determination of the doping concentration from the high intensity ac surface photovoltage requires that the light intensity for each doping concentration be set reproducibly at the same value; however, this value could be different for each doping concentration. The method therefore requires calibrating measurement system 11 using wafers with known values of the doping concentration. The approach involves measurement of light intensity dependence of δVₛ using wafers of several doping concentrations, the particular number of wafers being dependent on the required measurement range. The doping concentration of each calibration sample is established under low intensity conditions (when δVₛ is proportional to Φ/ω), thereby allowing for the determination of the calibration factor at desired intensity. The advantage of a high intensity measurement is that there is a direct improvement of the signal-to-noise ratio. By comparison, low intensity measurements during calibration would be performed by averaging results over a longer period of time to improve accuracy of the calibration.

It should be noted that system 111 preferably uses a single light source 115 that can be used on layers in sample 11 that are thick enough so that generated minority carriers are essentially (predominantly) collected within top layer 19. In addition, system 111 is also applicable to semiconductor structures with an active junction region that experience a negligible photovoltaic effect associated with the active junction region due to its poor quality (e.g., p-type GaN deposited on an n-type buffer layer). Similarly, system 111 with single light source 115 is applicable to semiconductor structures with a high quality hetero-junction region embedded under the illuminated layer when the junction region is located far enough from the illuminated surface so as not to interfere with the SPMC measurement. This last condition implies that the layer exposed to the illumination be substantially thicker than the “light penetration depth” of the illumination used for measurements.

It should also be noted that when the hetero junction region is embedded under an illuminated cladding layer that is not thick enough to prevent generation of carriers within the junction region or their diffusion from the bulk of the layer towards the junction region, the optically generated carriers would produce both Surface Photovoltage (SPV) and Junction Photovoltage (JPV). Accordingly, the characterization of such wafer structure is accomplished using two light beams of substantially different wavelengths, the light beams being generated from either a pair of light sources or a single light source with filters that allow for wavelength modification.

As referenced briefly above, the photon energy of the first illumination source is preferably higher than the band-gap of the illuminated layer. Because of the thickness of the illuminated layer, it is to be understood that some charge carriers are generated in the vicinity of both the surface space-charge region and the junction space-charge region. The resulting signal is therefore the sum of the Surface Photovoltage and Junction Photovoltage.

In order to ensure that radiation produced in the active junction region 17 is efficiently emitted from the semiconductor sample 11, top cladding layer 19 needs to be essentially transparent to this radiation. Accordingly, top cladding layer 19 of semiconductor sample 11 is preferably constructed from a semiconductor material with a larger band-gap than active junction region 17.

As noted above, the photon energy of the second illumination source is essentially lower than the band-gap of the illuminated layer (e.g., top cladding layer 19). Since hetero-junction in the semiconductor sample (i.e., its active LED region) is formed by layers of semiconductor material with a smaller band-gap than its outer side cladding layers, the photovoltaic signal produced by the second illumination source is predominantly associated with active junction region 17.

It should be noted that the electrical characterization of active junction region 17 could be achieved using alternative techniques. For example, the first measurement is taken in a similar manner as described above to characterize both subsurface region 25 and active junction region 17 of semiconductor sample 11. However, the second measurement is made by illuminating the sample with an additional unmodulated, longer wavelength second illumination. This second illumination is preferably of high enough intensity to suppress junction photovoltage. As a result, the measured photovoltage is predominantly associated with top layer 19. Subtracting in-phase and quadrature components of the second measured photovoltage (i.e., associated with top cladding layer 19) from the first measured photovoltage (i.e., associated with both subsurface region 25 and active junction region 17) results in photovoltage associated only with active junction region 17.

In another variant of the present invention, a method of characterizing electrical properties of active junction region 17 exploits the presence of the electrostatic barrier by determining the space-charge (depletion) capacitance associated with this barrier using non-contact means. The measurement of the space-charge capacitance uses a Junction Photovoltage Measured Capacitance (JPMC) method that includes illuminating the wafer structure with periodically intensity modulated electromagnetic radiation having a photon energy that is greater than the band gap of layers forming the hetero-junction. The electromagnetic radiation is of sufficiently low intensity to minimize steady-state change of the potential barrier and thereby maintain it close to its dark value. The electromagnetic radiation is provided by using light with the photon energies below the value corresponding to the main absorption edge of the cladding layer. In the case of a GaN cladding layer, this photon energy falls preferably below approximately 3.5 eV, which corresponds to a wavelength that exceeds about 355 nm.

It should be noted that junction region characterization using the techniques set forth above is preferentially performed on a semiconductor sample 11 with an active junction region 17 made from materials with a lower energy gap than its cladding layers; however, it is to be understood that characterization of the junction region could be similarly performed on a semiconductor wafer structure with an active junction region that is made of the same material as its cladding layers. In this case, it is necessary that the photovoltage associated with the external cladding layer be negligible, which exists either for high quality junctions with low carrier recombination rate and/or when the doping level of the external cladding layers is relatively high and the surface photovoltage signal is negligible as compared to the junction photovoltage. The embodiments of this invention permit characterization of the active junction region using photon energy that generates carriers in both the cladding layer and in the junction region and therefore could be performed for both homo-junction and hetero junction based wafer structures.

Under open-circuit conditions at low illumination (low signal), the real (in-phase) and imaginary (quadrature) components of the signal associated with the junction region (neutral region) are described by formulas essentially similar to those describing signal associated with the surface photovoltage:

$$\begin{matrix}Re ( δ {V}_{j} ) = {C}_{j}^{- 1} \frac{δ {J}_{p h}}{ω} \frac{ω {τ}_{j}}{1 + {ω}^{2} {τ}_{j}^{2}} and & ( E ) \\ Im ( δ {V}_{j} ) = - {C}_{j}^{- 1} \frac{δ {J}_{p h}}{ω} \frac{{ω}^{2} {τ}_{j}^{2}}{1 + {ω}^{2} {τ}_{j}^{2}} & ( F )\end{matrix}$$

where subscripts “j” refer to the junction parameters, δJₚₕ is an ac component of the sinusoidally modulated light-induced current density in the junction region given by

δJₚₕ=δJₚₕₒ[1−exp(−αW_{D})] (G)

where δJₚₕₒ is an ac component of the light-induced current density corresponding to the infinite depletion region width, α is an absorption coefficient in the junction region, and W_{D} is a width of the junction space-charge depletion region (sometimes referred as a neutral, quasi-neutral region or simply junction width). The polarity of the light-induced current depends on the measurement configuration—on which side of the junction is in the proximity of the pick-up electrode.

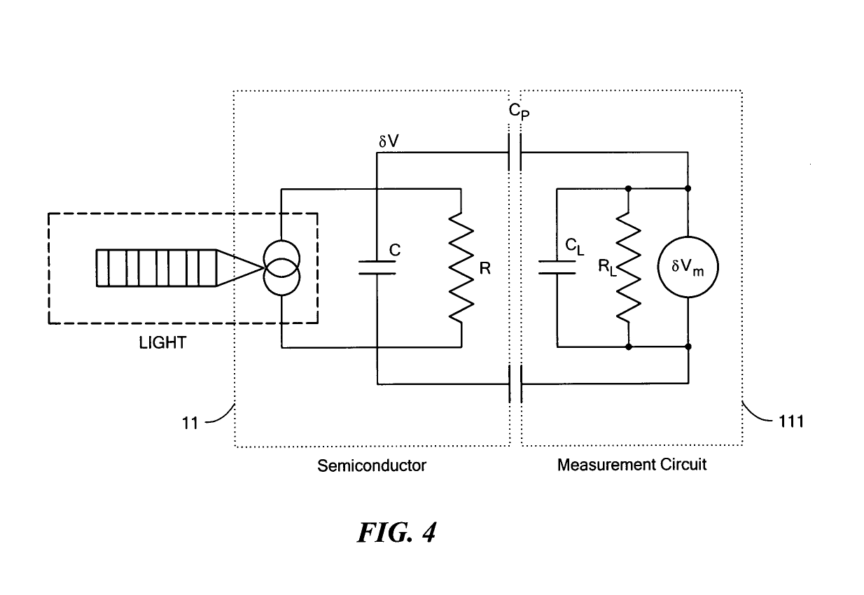

Referring now to FIG. 4, there is shown a simplified schematic representation of measurement system 111 being used to electrically characterize a semiconductor sample 11. As can be appreciated, equations E and F (as well as Equation A) correspond to the equivalent circuit representing both SPMC and JPMC measurement of semiconductor sample 11. In the case of SPMC measurement, the capacitance C corresponds to the surface space-charge (depletion) capacitance C_{sc} and R corresponds to the resistance Rₛ associated with the carrier recombination at the surface. In the case of JPMC measurement, the capacitance C corresponds to the depletion or junction capacitance Cⱼ and R corresponds to the junction shunt resistance Rₛₕ associated with the junction leakage. The time constant, τⱼ, for the junction is given by

$$\frac{1}{ω {τ}_{j}} = - \frac{Re ( δ {V}_{j} )}{Im ( δ {V}_{j} )} . \qquad ( H )$$

Since the junction capacitance Cⱼ=∈ₛ/W_{D}, the width of the junction depletion region can be calculated using the following formula:

$${W}_{D} = - \frac{{ɛ}_{s}}{δ {J}_{p h}} ω Im ( δ {V}_{j} ) ( 1 + \frac{1}{{ω}^{2} {τ}_{j}^{2}} ) \qquad ( I )$$

and since the time constant, τⱼ=RₛₕCⱼ

$${R}_{sh} = \frac{{W}_{D}}{{ɛ}_{s}} {τ}_{j} \qquad ( J )$$

For a two-sided abrupt homo-junction, the junction width (width of the junction neutral region), W_{D}, relates to material properties in the junction region through:

$${W}_{D} = \frac{{ɛ}_{s}}{{C}_{j}} = \sqrt{\frac{2 {ɛ}_{s}}{q} \cdot \frac{{N}_{A} + {N}_{D}}{{N}_{A} \cdot {N}_{D} } \cdot {V}_{D}} \qquad ( K )$$

where q is an elementary charge; ∈ₛ is the dielectric constant in the junction region; N_{A} and N_{D} are doping concentrations of acceptors and donors in the junction region and V_{D} is a build-in junction potential. Since under forward bias conditions minority carriers diffuse into the neutral region where they recombine producing radiation, the width of the junction or the width of the junction neutral region, W_{D}, is a critical parameter for the operation of an LED. This parameter depends on doping and the composition of the materials forming the embedded junction region and hence W_{D} or Cⱼ could be used to monitor uniformity and quality of the junction region in the LED wafer structure.

The calibration of the second light source, determination of δJₚₕₒ, requires a calibration wafer of known junction characteristics such as junction width. This junction width could be independently determined using X-ray techniques that are well known in the art.

Calibration of the junction related signal component induced by the first light source requires a wafer with not only known junction characteristics, such as junction width, but also negligible contribution due to the top cladding layer. This condition could be accomplished by producing a wafer with high doping concentration of the top cladding layer. Use of such a calibration wafer can also be used to establish a scaling factor that, in turn, can be utilized to determine the contribution of the junction related signal when measuring with the second light source.

Use of the above described calibration procedure allows for complete electrical characterization of the LED wafer structure. To perform such characterization, each point of the wafer is measured twice, the first measurement being performed using the modulated first illumination and the second measurement being performed using the modulated second illumination. In turn, the in-phase and quadrature components of the signal measured with the second illumination are scaled proportionally by a scaling factor, which is preferably determined with the calibration wafer, and then are subtracted from the in-phase and quadrature components of the signal measured with the first illumination. This subtraction results in a calculated signal that represents components associated with the top cladding layer and the junction photovoltage. Analysis of data and extraction of the wafer characteristics for both the top layer and the junction is performed further using formulas A through J of this invention.

### System Calibration

The following sets forth one useful way to correlate measured photovoltaic signals with electrical parameters of top cladding layer 19 and embedded junction region 17. It should be noted that the calibration process set forth below refers to specific systems outlined in detail above. However it is to be understood that other suitable systems may be used in place thereof without departing from the spirit of the present invention. The calculations outlined below may be performed by a processor in controller 119 or using an additional computer with executable software.

Referring now to FIGS. 2-4, wafer support 121 is in direct contact with the back surface of the wafer sample (i.e., sapphire substrate 13 for wafer sample 11) and pickup electrode 133 is separated from the outer surface of the wafer structure by a gap that is preferably less than 0.1 mm. As a result of the close proximity, top and bottom layers (e.g., layers 17 and 19 of semiconductor wafer 11) are capacitively coupled to electrodes 133 and wafer support 121, respectively.

As noted above, light source 115 is configured to direct a collimated beam of light through pickup electrode 133 so as to illuminate a measured spot of the outer surface of the wafer structure. In response, the intensity modulated light beam generates an alternating current (AC) photovoltaic signal that is picked up by the capacitively coupled pickup electrode 133. The signal is then amplified by both preamplifier 135 and lock-in amplifier 137, frequency filtered and time averaged to reduce noise, digitally converted by A/D coverter 139 and received by controller 119 for further analysis.

As can be appreciated, δV is the ac signal at the front surface of the semiconductor wafer structure that is induced by the periodically modulated illumination. C_{sc} represents the space-charge capacitance associated with the front surface of the wafer structure or with the buried junction, as discussed above, and R represents a resistance associated with the carrier recombination at the surface and in the space-charge region or shunt resistance of the buried junction. Cₚ is a total of the coupling capacitance between wafer support 121 and the back of the wafer structure and between front of the wafer structure and pickup electrode 133. C_{L} and R_{L} represent input impedance (load) of preamplifier 135 and δVₘ is the measured ac-photovoltaic signal. The relation between δVₘ and δV is:

$$δ {V}_{m} = δ {V ( 1 + \frac{{Z}_{p} + {Z}_{sc}}{{Z}_{L}} )}^{- 1} \qquad ( L )$$

where Zₚ is the total coupling impedance between the semiconductor and the input of preamplifier 135, Z_{sc} is the total impedance of the space-charge region and Z_{L} is the input impedance of detection subsystem 117.

At frequencies high enough so that impedance of the surface space-charge region is dominated by the space-charge capacitance,

$$δ {V}_{m} = δ {V [ 1 + {C}_{L} ( \frac{1}{{C}_{p}} + \frac{1}{{C}_{sc}} ) ]}^{- 1} \qquad ( M )$$

where C_{sc} represents space-charge capacitance referenced to the probed area (dimension in Farads, F, and not F/cm²).

The proportionality factor between δVₘ and δV could be determined in this case by applying a known AC voltage, Vᵣ, and measuring the corresponding output voltage, Vᵣₘ. Since C_{sc} is much larger than other capacitances in this circuit, the proportionality factor is determined by the ratio of Vᵣ/Vᵣₘ and

$$δ V = δ {V}_{m} \frac{{V}_{r}}{{V}_{rm}} . \qquad ( N )$$

In the preferred embodiment, the signal from the fast photodiode (with no phase shift) or the signal corresponding to the LED current and the reference AC voltage used to correct for the wafer-probe coupling capacitance are applied simultaneously to chuck 121. The photodiode signal or the LED current is then measured with lock-in amplifier 137 at the same frequency, f₁, as the signal from the wafer. The photodiode or LED current signal measurement and phase adjustment are performed before and/or after actual measurement of the wafer. Since the photodiode or LED current signal is set to be in-phase with the light modulation, the phase adjustment is performed by adjusting phase in a primary lock-in amplifier 137 until switching on and off of the photodiode or LED current signal does not produce any changes in the imaginary (quadrature) component of the signal. The gap correction signal, δVᵣₘ, is then measured using a secondary lock-in amplifier 137 at a frequency f₂ that differs from the frequency f₁ of the primary lock-in amplifier 137. The frequency f₂ is preferably higher than f₁, with frequency f₂ being high enough not to interfere with measurement of the wafer signal but close enough not to distort gap related signal correction. Frequency f₂ is preferably less than 2f₁. Specifically, in the preferred embodiment, f₁ is about 3.5 kHz and f₂ is about 4.5 kHz.

It should be noted that the above-described approach calibrates not only the coupling between the semiconductor wafer structure and detection subsystem 117 but the entire gain and phase shift of subsystem 117. When combined with the absolute measurement of the incident illumination and wafer reflectance, system 111 is effectively calibrated for independent determination of the wafer structure characteristics.

Measurement of the incident illumination (flux) could be performed with a UV power meter with a UV sensor (phototube) sensitized to a wavelength corresponding to the light source (such as Hamamatsu UV Power Meter C9536/H9535-254).

Alternatively, photon flux could be calibrated using n-type GaN. The doping concentration of the n-type GaN could be calibrated using Hall effects and then correlated with the SPMC measurements.

Due to the fact that the extent of dopant (e.g., Mg) activation in GaN (i.e., the concentration of electrically active unpassivated acceptors) is not known, the aforementioned approach, when combined with, inter alia, SIMS measurements, would allow for the determination of the efficiency of the dopant activation processes used in the HB-LED manufacturing, which is one of the objects of the present invention.

It should be noted that comparing electrically active doping concentrations determined using embodiments of this invention with carrier concentrations determined using Hall effects could be used to determine effective ionization energy of dopants, which is highly desirable.

In the preferred embodiment, the Vᵣ/Vᵣₘ ratio is preferably kept at a near constant value for all measured wafer structures either for the manufacturing line or for a specific device.

The flatness of sapphire substrate 13 may not require monitoring during wafer measurement after placing the wafer on wafer support 121. If the flatness of the substrate does not meet production requirements, the Vᵣₘ signal can be used in a feedback loop to control positioning of pickup electrode 129 using the motorized stage.

### Actual Measured Results Using Method of Present Invention

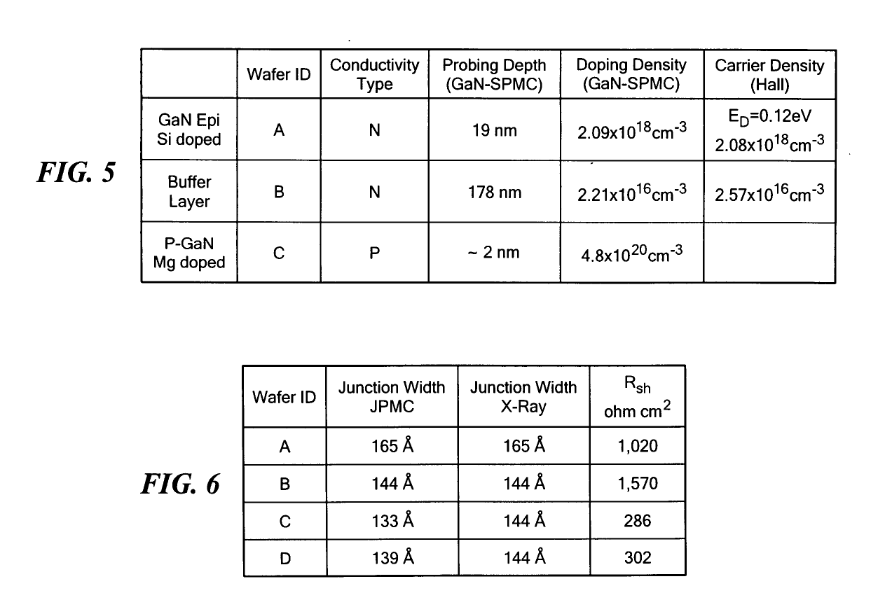

Referring now to FIG. 5, there is shown a chart listing actual measurements of the doping concentration and conductivity type for three different GaN-based semiconductor samples using the system and method of electrical characterization of the present invention, the three samples including: (a) an intentionally undoped buffer layer, (b) a Si-doped GaN layer grown on the buffer layer, (c) a Mg-doped GaN layer grown on a buffer layer. The chart additionally includes conventional Hall measurements that were made for comparative purposes.

As can be seen, the results for the n-type layers demonstrate good correlation with the Hall measurements. Some differences between these two measurements may be attributed to the fact that the methods of the present invention measure local values while Hall measurements are made on separate 10×10 mm samples. It should be noted that the conductivity type was determined from the polarity of the Imaginary and Real components of the photovoltaic signal. In addition, it should be noted that the probing depth corresponds to the width of the space charge region W.

Referring now to FIG. 6, there is shown a chart listing actual measurements of the junction width and shunt resistance for four different semiconductor wafer samples used in the LED industry. The chart additionally includes X-ray measurements for comparative purposes.

As can be seen, the results generated using the system and method of the present invention demonstrate good correlation with the X-ray measurements. Some differences between these two measurements may be attributed to the wafer non-uniformity and the fact that the present invention determines electrical width of the junction while X-ray is measuring crystallographic width of the layers.

The embodiments of the present invention described above are intended to be merely exemplary and those skilled in the art shall be able to make numerous variations and modifications to it without departing from the spirit of the present invention. All such variations and modifications are intended to be within the scope of the present invention as defined in the appended claims.

What is claimed is:

1. A method for characterizing electrical properties of a semiconductor sample, the semiconductor sample comprising an active junction region disposed between at least one top cladding layer and at least one bottom cladding layer, the at least one top cladding layer having an exposed outer surface and a subsurface region beneath the exposed outer surface, the exposed outer surface having a surface-state charge that forms an electrostatic barrier, the method comprising the steps of:
(a) illuminating the outer surface of the at least one top cladding layer with a first intensity modulated light beam that penetrates through the at least one top cladding layer and into the active junction region so as to produce charge carriers in both the subsurface region of the at least one top cladding layer and the active junction region, the first intensity modulated light beam being adapted to preserve the electrostatic barrier and thereby yield a first photovoltage signal on the exposed outer surface that represents electrical properties associated with both the subsurface region of the at least one top cladding layer and the active junction region;
(b) measuring the first photovoltage signal on the exposed outer surface of the semiconductor sample;
(c) illuminating the exposed outer surface of the at least one top cladding layer with a second intensity modulated light beam that penetrates through the at least one top cladding layer and into the active junction region, the second intensity modulated light beam being adapted to produce a second photovoltage signal on the exposed outer surface that represents electrical properties associated only with the active junction region;
(d) measuring the second photovoltage signal on the exposed outer surface of the semiconductor sample; and
(e) subtracting the second photovoltage signal from the first photovoltage signal to yield a sample characterization signal, the sample characterization signal representing electrical properties associated with the subsurface region of the at least one top cladding layer.

2. The method of claim 1 wherein the photon energy of the first intensity modulated light beam is greater than the band gap of the at least one top cladding layer.

3. The method of claim 1 wherein the second intensity modulated light beam is adapted to produce charge carriers in both the subsurface region of the at least one top cladding layer and the active junction region, the second intensity modulated light beam being additionally adapted to collapse the electrostatic barrier in the at least one top cladding layer and thereby yield the second photovoltage signal that represents electrical properties associated with only the active junction region.

4. The method of claim 1 wherein the photon energy of the second intensity modulated light beam is less than the band gap of the at least one top cladding layer and greater than the band gap of the active junction region.

5. The method of claim 1 wherein the second intensity modulated light beam is adapted produce charge carriers in only the active junction region and thereby yield the second photovoltage signal that represents electrical properties associated with only the active junction region.

6. The method of claim 1 wherein at least one of the first and second intensity modulated light beams is modulated sinusoidally.

7. The method of claim 6 wherein the second intensity modulated light beam is filtered through a filter at least a portion of which is constructed as the same material as the least one top cladding layer.

8. The method of claim 7 wherein the filter has a thickness in the range of approximately 10 to 500 micrometers.

9. The method of claim 1 wherein the first intensity modulated light beam illuminates the semiconductor sample for a first duration and the second intensity modulated light beam illuminates the semiconductor sample for a second duration.

10. The method of claim 9 wherein the first duration is shorter than the second duration.

11. The method of claim 10 wherein the first duration is in the range of approximately 10 milliseconds to 100 milliseconds.

12. The method of claim 11 wherein the second duration is at least approximately 1 seconds.

13. The method of claim 1 wherein the first and second illumination steps are achieved using a single illumination source.

14. The method of claim 1 wherein the first and second illumination steps are achieved using separate illumination sources.

15. The method of claim 1 wherein the first and second measurement steps are performed using a probe that is spaced at a near constant distance from the outer surface of the semiconductor sample.

16. The method of claim 1 further comprising the step of calculating the surface depletion width, W, at the exposed outer surface of the at least one top cladding layer using the following formula:
$$\vert Im ( δ {V}_{s} ) \vert = δ G \frac{qW}{{ɛ}_{s}} \frac{{ωτ}^{2}}{1 + {ω}^{2} {τ}^{2}} .$$

17. The method of claim 16 further comprising the step of calculating carrier lifetime, τ, in the exposed outer surface of the at least one top cladding layer using the following formula:
$$τ = - \frac{1}{ω} \frac{Im ( δ {V}_{s} )}{Re ( δ {V}_{s} )} .$$

18. The method of claim 17 further comprising the step of calculating the minority carrier generation rate in the surface depletion region at the exposed outer surface of the at least one top cladding layer using the following formula:
δG=(1−R)δΦ[1−exp(−αW)].

19. The method of claim 16 further comprising the step of calculating the doping concentration in the subsurface region of the at least one top cladding layer using the following formula:
$$\vert {N}_{D} - {N}_{A} \vert = \frac{2 {ɛ}_{s} \vert {V}_{s} \vert}{{qW}^{2}}$$

20. The method of claim 19 further comprising the step of calculating the height of the surface potential barrier, Vₛ, using the following formula:
qVₛ=E_{FS}−E_{F}.

21. The method of claim 20 wherein E_{FS} is the pinning energy of the Fermi level at the outer surface of the at least one top cladding layer.

22. The method of claim 20 wherein E_{FS} is approximately 2.55 eV above the valence band edge in both p-type and n-type GaN.

23. The method of claim 22 wherein E_{FS} is independently determined by comparing measurements of this method with another method such as Hall effect measurement.

24. The method of claim 20 wherein E_{F} is calculated iteratively using the doping concentration determined in the previous step of calculations.

25. The method of claim 1 further comprising the step of calculating the width of the active junction region using the following formula:
$${W}_{D} = - \frac{{ɛ}_{s}}{δ {J}_{ph}} ω Im ( δ {V}_{j} ) ( 1 + \frac{1}{{ω}^{2} {τ}_{j}^{2}} ) .$$

26. The method of claim 1 further comprising the step of calculating the shunt resistance of the active junction region using the following formula:
$${R}_{sh} = \frac{{W}_{D}}{{ɛ}_{s}} {τ}_{j} .$$

27. The method of claim 26 further comprising the step of calculating the time constant, τⱼ, for the active junction region using the following formula:
$$\frac{1}{ω {τ}_{j}} = - \frac{Re ( δ {V}_{j} )}{Im ( δ {V}_{j} )} .$$

28. The method of claim 26 further comprising the step of determining an AC component of the intensity modulated light-induced current density in the junction region, δJₚₕ, and thereby calibrating the second intensity modulated light beam, by comparing W_{D} with the active junction region width that has been independently determined using X-ray techniques.

29. A method for characterizing electrical properties of a semiconductor sample, the semiconductor sample comprising a top layer having an exposed outer surface and a subsurface region beneath the exposed outer surface, the exposed outer surface having a surface-state charge that forms an electrostatic barrier, the method comprising the steps of:
(a) illuminating the exposed outer surface of the top layer with an intensity modulated light beam of a photon energy that exceeds the band gap of the top layer and thereby produces charge carriers at the exposed outer surface of the top layer, the intensity modulated light beam being adapted to preserve the electrostatic barrier to yield a photovoltage signal on the exposed outer surface that represents electrical properties associated with both the exposed outer surface and the subsurface region of the top layer; and
(b) measuring the photovoltage signal on the exposed outer surface of the semiconductor sample.

30. The method of claim 29 wherein the photon energy of the intensity modulated light beam is greater than the band gap of the top layer.

31. The method of claim 29 wherein the intensity modulated light beam is modulated sinusoidally.

32. The method of claim 29 wherein the measurement step is performed using a probe that is spaced at a near constant distance from the outer surface of the semiconductor sample.

33. The method of claim 29 further comprising the step of calculating the surface depletion width, W, at the exposed outer surface of the top layer using the following formula:
$$\vert Im ( δ {V}_{s} ) \vert = δ G \frac{qW}{{ɛ}_{S}} \frac{{ωτ}^{2}}{1 + {ω}^{2} {τ}^{2}} .$$

34. The method of claim 33 further comprising the step of calculating carrier lifetime, t, in the exposed outer surface of the top layer using the following formula:
$$τ = - \frac{1}{ω} \frac{Im ( δ {V}_{s} )}{Re ( δ {V}_{s} )} .$$

35. The method of claim 34 further comprising the step of calculating the minority carrier generation rate in the surface depletion region at the exposed outer surface of the top layer using the following formula:
δG=(1−R)δΦ[1−exp(−αW)].

36. The method of claim 32 further comprising the step of calculating the doping concentration in the subsurface region of the top layer using the following formula:
$$\vert {N}_{D} - {N}_{A} \vert = \frac{2 {ɛ}_{s} \vert {V}_{s} \vert}{{qW}^{2}} .$$

37. The method of claim 36 further comprising the step of calculating the height of the surface potential barrier, Vₛ, using the following formula:
qVₛ=E_{FS}−E_{F}.

38. The method of claim 37 wherein E_{FS} is the pinning energy of the Fermi level at the outer surface of the at least one top cladding layer.

39. The method of claim 37 wherein E_{FS} is approximately 2.55 eV above the valence band edge in both p-type and n-type GaN.

40. The method of claim 39 wherein E_{FS} is independently determined by comparing measurements of this method with another method such as Hall effect measurement.

41. The method of claim 39 wherein E_{F} is calculated iteratively using the doping concentration determined in the previous step of calculations.

42. A method for characterizing electrical properties of a semiconductor sample, the semiconductor sample comprising an active junction region disposed between at least one top cladding layer and at least one bottom cladding layer, the at least one top cladding layer having an exposed outer surface and a subsurface region beneath the exposed outer surface, the exposed outer surface having a surface-state charge that forms an electrostatic barrier, the method comprising the steps of:
(a) illuminating the outer surface of the at least one top cladding layer with an intensity modulated light beam having a photon energy level that is lower than the band gap of the at least one top cladding layer and higher than the layers forming the active junction region, the intensity modulated light beam being adapted to penetrate through the at least one top cladding layer and into the active junction region so as to produce charge carriers in only the active junction region and thereby yield a photovoltage signal on the exposed outer surface that represents electrical properties associated with only the active junction region; and
(b) measuring the photovoltage signal on the exposed outer surface of the semiconductor sample.

43. The method of claim 42 wherein the intensity modulated light beam is modulated sinusoidally.

44. The method of claim 42 wherein the intensity modulated light beam has a wavelength longer than approximately 355 nm.

45. The method of claim 42 wherein the intensity modulated light beam is filtered through a filter at least a portion of which is constructed as the same material as the least one top cladding layer.

46. The method of claim 42 wherein a portion of the filter constructed as the same material as the least one top cladding layer has a thickness in the range of approximately 10 to 500 micrometers.

47. The method of claim 42 wherein the measurement step is performed using a probe that is spaced at a near constant distance from the outer surface of the semiconductor sample.

48. The method of claim 42 further comprising the step of calculating the width of the active junction region using the following formula:
$${W}_{D} = - \frac{{ɛ}_{s}}{δ {J}_{ph}} ωIm ( δ {V}_{j} ) ( 1 + \frac{1}{{ω}^{2} {τ}_{j}^{2}} ) .$$

49. The method of claim 42 further comprising the step of calculating the shunt resistance of the active junction region using the following formula:
$${R}_{sh} = \frac{{W}_{D}}{{ɛ}_{s}} {τ}_{j} .$$

50. The method of claim 49 further comprising the step of calculating the time constant, τⱼ, for the active junction region using the following formula:
$$\frac{1}{{ωτ}_{j}} = - \frac{Re ( δ {V}_{j} )}{Im ( δ {V}_{j} )} .$$

51. The method of claim 49 further comprising the step of determining an AC component of the intensity modulated light-induced current density in the junction region, δJₚₕ, and thereby calibrating the second intensity modulated light beam, by comparing W_{D} with the active junction region width that has been independently determined using X-ray techniques.

52. A system for characterizing electrical properties of a semiconductor sample, the semiconductor sample comprising an active junction region disposed between at least one top cladding layer and at least one bottom cladding layer, the at least one top cladding layer having an exposed outer surface and a subsurface region beneath the exposed outer surface, the exposed outer surface having a surface-state charge that forms an electrostatic barrier, the system comprising:
(a) a support subsystem for supporting the semiconductor sample;
(b) at least one light source for illuminating at least a region of the outer surface of the at least one top cladding layer to excite charge carriers with the semiconductor sample so as to create a surface photovoltage signal;
(c) a detection subsystem for measuring the surface photovoltage signal; and
(d) a controller in electrical communication with the detection subsystem for analyzing the surface photovoltage signal to characterize electrical properties of the semiconductor sample;
(e) wherein the at least one light source illuminates the semiconductor sample with at least one intensity modulated light beam that penetrates through the at least one top cladding layer and into the active junction region so as to produce charge carriers in both the subsurface region of the at least one top cladding layer and the active junction region, the first intensity modulated light beam being adapted to preserve the electrostatic barrier and thereby yield a first photovoltage signal on the exposed outer surface that represents electrical properties associated with both the subsurface region of the at least one top cladding layer and the active junction region, the at least one light source additionally illuminating the semiconductor sample with a second intensity modulated light beam that penetrates through the at least one top cladding layer and into the active junction region, the second intensity modulated light beam being adapted to produce a second photovoltage signal on the exposed outer surface that represents electrical properties associated only with the active junction region.

53. The system of claim 52 wherein the controller subtracts the second photovoltage signal from the first photovoltage signal to yield a sample characterization signal, the sample characterization signal representing electrical properties associated with the subsurface region of the at least one top cladding layer.

54. The system of claim 52 wherein the support subsystem includes a wafer support that is adapted for regulated displacement in order to illuminate various regions of the semiconductor sample.

55. The system of claim 52 wherein the detection subsystem includes a pick-up electrode spaced a near constant distance from the exposed outer surface of the semiconductor sample.

56. The system of claim 52 wherein the photon energy of the first intensity modulated light beam is greater than the band gap of the at least one top cladding layer.

57. The system of claim 52 wherein the second intensity modulated light beam is adapted to produce charge carriers in both the subsurface region of the at least one top cladding layer and the active junction region, the second intensity modulated light beam being additionally adapted to collapse the electrostatic barrier in the at least one top cladding layer and thereby yield the second photovoltage signal that represents electrical properties associated with only the active junction region.

58. The system of claim 57 wherein the photon energy of the second intensity modulated light beam is less than the band gap of the at least one top cladding layer and greater than the band gap of the active junction region.

59. The system of claim 52 wherein the second intensity modulated light beam is adapted produce charge carriers in only the active junction region and thereby yield the second photovoltage signal that represents electrical properties associated with only the active junction region.

60. The system of claim 52 wherein at least one of the first and second intensity modulated light beams is modulated sinusoidally.

61. The system of claim 60 further comprising a filter through which the second intensity modulated light beam is passed, at least a portion of the filter being constructed from the same material as the least one top cladding layer.

62. The system of claim 60 wherein the filter has a thickness in the range of approximately 10 to 500 micrometers.

63. The system of claim 59 wherein the first intensity modulated light beam illuminates the semiconductor sample for a first duration and the second intensity modulated light beam illuminates the semiconductor sample for a second duration.

64. The system of claim 63 wherein the first duration is shorter than the second duration.

65. The system of claim 64 wherein the first duration is in the range of approximately 10 milliseconds to 100 milliseconds.

67. The system of claim 66 wherein the second duration is at least approximately 1 second.
